(19) United States
(12) Patent Application Publication
(10) Pub. No.: US 2017/0125735 A1
(43) Pub. Date: May 4, 2017

(54) ELECTROLUMINESCENT DEVICE

(71) Applicant: National Taiwan University, Taipei (TW)

(72) Inventors: Chung-Chih Wu, Taipei (TW); Chun-Yang Lu, Taipei (TW); Wei-Kai Lee, Taipei (TW); Min Jiao, Taipei (TW)

(21) Appl. No.: 15/332,378

(22) Filed: Oct. 24, 2016

Related U.S. Application Data
(60) Provisional application No. 62/285,462, filed on Oct. 30, 2015.

(51) Int. Cl. H01L 51/52

(52) U.S. Cl. CPC H01L 51/5262; H01L 51/5203

(57) ABSTRACT

An electroluminescent device is provided. The electroluminescent device includes a substrate or superstrate, an optical out-coupling structure, a first electrode, a functional stack, and a second electrode. The substrate has an outer surface and an opposite inner surface. The optical out-coupling structure situates on the outer surface. The first electrode is disposed on the inner surface. The first electrode is transparent and has a refractive index equal to or less than 1.7. The functional stack is disposed on the first electrode and includes a light emitting layer. The light emitting layer contains an emitting material having preferential horizontal emitting dipoles with a horizontal dipole ratio being equal to or larger than 70%. The second electrode is disposed on the functional stack.

### CROSS-REFERENCE TO RELATED APPLICATION

This application claims priority to and the benefit of U.S. Provisional Patent Application Ser. No. 62/285,462, filed on Oct. 30, 2015, and entitled “Electroluminescent devices with high optical out-coupling efficiencies”, the disclosure of which is incorporated by reference in its entirety.

### FIELD OF THE INVENTION

The present invention pertains to an electroluminescent (EL) device, and more particularly pertains to an organic light-emitting device (OLED) structures with improved optical out-coupling, external quantum efficiencies and their applications.

### BACKGROUND OF THE INVENTION

Since the reports of efficient and practical organic light-emitting device (OLEDs) in 1987 by Tang and VanSlyke, OLEDs have been subjects of intensive studies and development for displays and lighting applications.

Please refer to FIG. 1, which shows a schematic structure of a known OLED. A typical OLED has an organic layer(s) sandwiched between one reflective metal electrode (usually cathode) and one transparent indium tin oxide (ITO) electrode (usually anode) on glass substrate. By adopting efficient emitting materials such the phosphorescence mechanisms, the internal quantum efficiencies of OLEDs can reach nearly 100%. However, in typical OLED structures, the optical out-coupling of OLED internal emission to air is an issue for achieving high external quantum efficiencies. Usually, the ITO and organic layers have higher refractive indices (n; n˜1.8-2.1 for ITO and ˜1.7-1.8 for organic layers in OLEDs) than the typical substrates (e.g., glasses and plastics etc., n˜1.4-1.5) and air (n=1). Thus, due to the significant refractive-index mismatches at air/substrate and substrate/ITO interfaces in typical OLEDs, OLED internal emission usually suffers total internal reflection and hence most of internal radiation is trapped and guided inside the device.

Please refer to FIG. 2, which illustrates four different radiation modes coupled in a known OLED. In general, internal radiation in OLEDs is coupled into four different modes: (1) radiation modes that are outcoupled to air as useful emission, (2) substrate modes that are trapped and waveguided in the substrate, (3) waveguided (WG) modes that are trapped and waveguided in the high-index organic/ITO layers, and (4) surface-plasmon (SP) modes that are guided along the organic/metal interface. Thus, the out-coupling efficiency of conventional and typical OLED devices is usually only about 20-25%, and there is a great demand in enhancement in external quantum efficiency (EQE) of OLEDs by increasing the light out-coupling, in particular for applications that impose strong requirements on power efficiencies (e.g., lighting and mobile applications etc.).

### SUMMARY OF THE PRESENT INVENTION

In order to overcome the drawbacks of prior arts, an electroluminescent device that at least includes a first electrode having a low refractive index and a light emitting layer having horizontal emitting dipoles with a high horizontal dipole ratio is provided.

Researches reveal that emitters having preferential in-plane (horizontal) emitting dipoles are beneficial to optical out-coupling (light extraction) of OLEDs using the conventional high-refractive-index transparent electrode ITO, since the number (ratio) of vertical emitting dipoles contributing little to external emission is reduced and the radiation pattern of a horizontal emitting dipole is in general more suitable for optical out-coupling.

Here this invention discloses that by combining the emitters having preferential in-plane (horizontal) emitting dipoles, the low-refractive-index transparent electrode, and a substrate or superstrate with an optical out-coupling treatment in an organic electroluminescent device, improved and very high optical out-coupling efficiency and external quantum efficiency can be achieved.

According to one aspect, the present invention discloses an electroluminescent device. The electroluminescent device includes a substrate or superstrate, an optical out-coupling structure, a first electrode, a functional stack, and a second electrode. The substrate or superstrate has an outer surface and an opposite inner surface. The optical out-coupling structure situates on the outer surface. The first electrode is disposed on the inner surface. The first electrode is transparent and has a refractive index equal to or less than 1.7. The functional stack is disposed on the first electrode and includes a light emitting layer. The light emitting layer contains an emitting material having preferential horizontal emitting dipoles with a horizontal dipole ratio being equal to or larger than 70%. The second electrode is disposed on the functional stack.

In certain embodiments, the refractive index of the first electrode is no smaller than a refractive index of the substrate or superstrate by more than 0.1.

In certain embodiments, the functional stack further includes at least one functional layer sandwiched between the light emitting layer and the second electrode. A thickness of the functional layer is chosen in the way so that the emitter-to-second-electrode round-trip optical path (phase change) be significantly larger than (2φ₁+φₘ=2pπ), where p is 0 or a natural number, φ₁ is a phase change (optical path) for a light having a main emission wavelength λ to travel from the light emitting layer to the second electrode, and φₘ is a phase change for the light being reflected by the second electrode.

In certain embodiments, the first electrode is selected from the group consisting essentially of PEDOT:PSS, nanoporous indium tin oxide (ITO), nanoporous fluorine-doped tin oxide, nanoporous aluminum zinc oxide, nanoporous gallium zinc oxide, nanoporous tin oxide, nanoporous niobium-doped titanium oxide, their stacking, and their combinations.

In certain embodiments, the out-coupling structure is an out-coupling optical element attached to the outer surface of the substrate or superstrate.

In certain embodiments, the out-coupling optical element is an optical lens, a hemisphere lens, a prism, a pyramid, a macrolens sheet, a microlens sheet, a micro-prism sheet, a micro-pyramid sheet, a micro-particle layer, a nano-particle layer, a microporous layer, a nanoporous layer, a grating sheet, a scattering sheet, a diffuser sheet, arrays of pores, arrays of crevices, arrays of air bubbles, or arrays of vacuum pores.

In certain embodiments, the out-coupling structure is provided with a regular pattern or an irregular pattern.

In certain embodiments, the optical out-coupling structure is the outer surface applied with an out-coupling surface treatment.

In certain embodiments, the out-coupling surface treatment is roughening the outer surface or shaping the outer surface to form prism, pyramid, macrolens, microlens, micro-prism, micro-pyramid, or grating.

In certain embodiments, the out-coupling structure is provided with a regular or irregular pattern.

In certain embodiments, when used in lighting or display panels, the device disclosed in this invention is integrated with metal bus lines or metal grids having high conductivity for current conduction and for uniform current spreading over larger areas.

In certain embodiments, the first electrode is either an anode or a cathode of the electroluminescent device, and the second electrode is the other.

### BRIEF DESCRIPTION OF THE DRAWINGS

FIG. 1 shows a schematic structure of a known OLED.

FIG. 2 illustrates four different radiation modes coupled in a known OLED.

FIG. 3a shows a schematic structure of an electroluminescent device according to one embodiment of the invention.

FIG. 3b shows a schematic structure of another electroluminescent device according to another embodiment of the invention.

FIGS. 4a and 4b show the measured and simulation results for CBP doped with 8 wt. % Ir(ppy)₂(acac) and Ir(ppy)₃ respectively.

FIG. 5a-5d show calculated φₐᵢᵣ as a function of the HTL (TAPC) and ETL (B3PYMPM) thicknesses for the four types of devices: [ITO, Ir(ppy)₃], [ITO, Ir(ppy)₂(acac)], [PEDOT, Ir(ppy)₃], [PEDOT, Ir(ppy)₂(acac)], respectively.

FIG. 5e-5h show calculated φ_{sub} for same four devices.

FIGS. 6a and 6b show φₐᵢᵣ and φ_{sub} as a function of the ETL thickness, respectively, at fixed and roughly optimal TAPC thicknesses for four device types.

FIG. 7a-7d show calculated mode distributions (fraction of internally generated radiation coupled into different modes as a function of kₜ/k₀; k₀ is the free-space wavevector) with varied ETL thicknesses (and fixed HTL thicknesses) for the four device types.

FIG. 7e-7f show the relative fractions (intensities) of SP modes and WG modes, respectively, as a function of the ETL thickness for these four device types.

FIG. 8a shows current-voltage-luminance (I-V-L) characteristics of all [ITO, Ir(ppy)₂(acac)] and [PEDOT, Ir(ppy)₂(acac)] devices tested (without lens attachment).

FIG. 8b-8c show EQEs and luminous efficiencies (η_{L}) of all Ir(ppy)₂(acac) devices in FIG. 8a, measured either without or with lens attachment.

FIG. 8d shows current-voltage-luminance (I-V-L) characteristics of all [ITO, Ir(ppy)₃] and [PEDOT, Ir(ppy)₃] devices tested (without lens attachment).

FIG. 8e-8f show EQEs and luminous efficiencies (η_{L}) of all Ir(ppy)₃ devices in FIG. 8d, measured either without or with lens attachment.

FIG. 9a-9e show measured (symbols) and calculated (lines) EL spectra with relative intensities at viewing angles of 0°, 30°, and 60° off the surface normal for the lens-attached [PEDOT, Ir(ppy)₂(acac)] devices having an ETL thickness of 30-90 nm, respectively.

FIG. 9f shows measured (symbols) and calculated (lines) angular distributions of the EL intensity (normalized to 0° intensity) for these lens-attached devices, along with the Lambertian distribution.

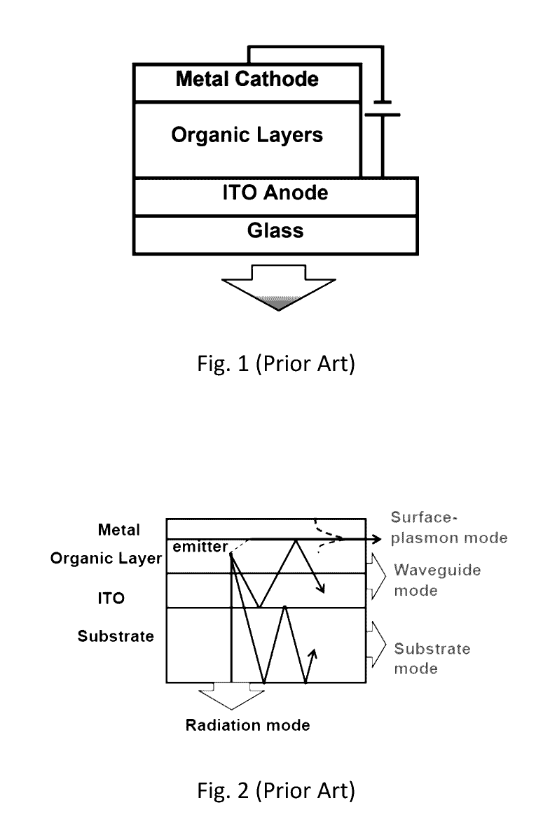

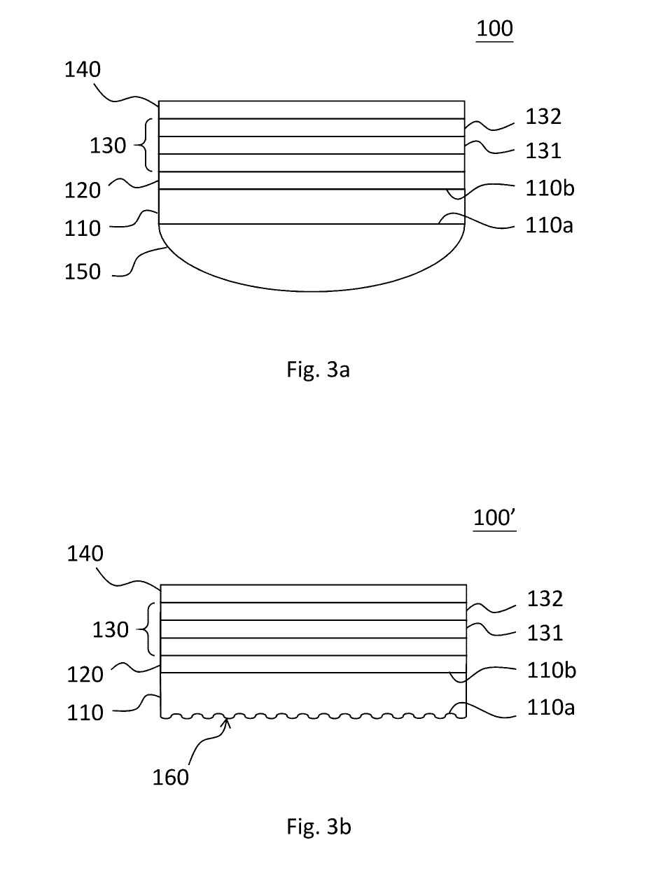

### DETAILED DESCRIPTION OF THE INVENTION

It is to be understood that both the foregoing general description and the following detailed description are exemplary and explanatory only and are not restrictive of the invention, as claimed. It should be noted that, as used in the specification and the appended claims, the singular forms “a”, “an” and “the” include plural referents unless the context clearly dictates otherwise. The use of the terms “contain”, “contains”, “containing”, “include”, “includes”, “including,” “have,” “has,” or “having” should be generally understood as open-ended and non-limiting unless specifically stated otherwise. The use of the direction terms “top”, “bottom”, “on”, “under”, “up”, “down”, “left, “right”, “front” or “rear”, etc. is only reference to the drawings. Thus, the direction is not limited in the present invention. References cited herein are hereby incorporated by reference in their entirety, except to the extent that they conflict with teachings explicitly set forth in this specification.

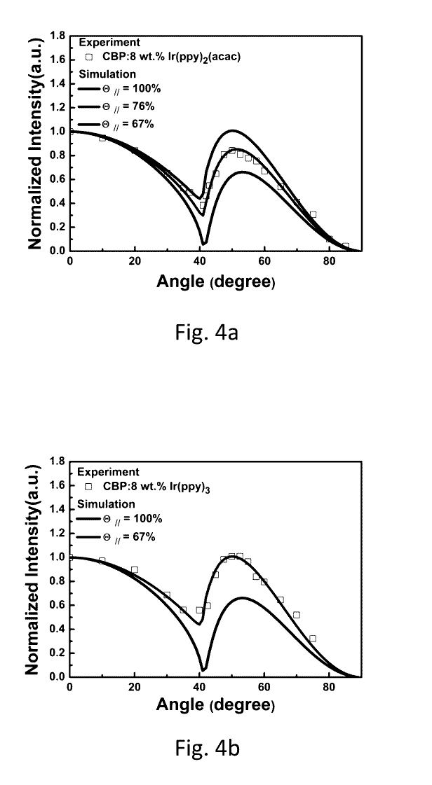

Please refer to FIG. 3a, which is a schematic structure of an electroluminescent device according to one embodiment of the invention. The electroluminescent device 100 includes a substrate or superstrate 110, an optical out-coupling structure 150, a first electrode 120, a functional stack 130, and a second electrode 140. The substrate or superstrate 110 has an outer surface 110a and an opposite inner surface 110b. The optical out-coupling structure 150 situates on the outer surface 110a. The first electrode 120 is transparent and is disposed on the inner surface 110b. The upper limit for a refractive index of the first electrode 120 is 1.7, and the lower limit for the refractive index of the first electrode 120 is about the index of the substrate or superstrate 110 (not smaller than the substrate index by more than 0.1). That is to say, the first electrode 120 is transparent and has the refractive index equal to or less than 1.7, or no smaller than the refractive index of the substrate or superstrate 110 by more than 0.1. Normally the known material of the substrate 110 (like plastic or glass) has a refractive index around 1.5; therefore, in this embodiment, the range of the refractive index of the first electrode 120 is from 1.4 to 1.7.

The functional stack 130 is disposed on the first electrode 120. The functional stack 130 includes a light emitting layer 131 containing an emitting material having preferential horizontal emitting dipoles with a horizontal dipole ratio being equal to or larger than 70%. The second electrode 140 is disposed on the functional stack 130.

The electroluminescent device 100 may further comprise one or more sub-layers from Layer 1 to Layer j, being sandwiched between the second electrode 140 and the light emitting layer 131. As shown in FIG. 3a, the functional stack 130 further includes at least one functional layer 132 sandwiched between the light emitting layer 131 and the second electrode 140. A thickness of the functional layer is chosen in the way so that the emitter-to-second-electrode round-trip optical path (phase change) be significantly larger than (2φ₁=φₘ=2pπ), where p is 0 or a natural number, φ₁ is a phase change (optical path) for a light having a main emission wavelength λ to travel from the light emitting layer to the second electrode, and φₘ is a phase change for the light being reflected by the second electrode 140 (e.g. the metal electrode of the device 100).

As shown in FIG. 3a, in the present embodiment, the out-coupling structure 150 is an out-coupling optical element attached to the outer surface 110a of the substrate or superstrate 110. The out-coupling optical element can be exemplified by an optical lens, a hemisphere lens, a prism, a pyramid, a macrolens sheet, a microlens sheet, a micro-prism sheet, a micro-pyramid sheet, a micro-particle layer, a nano-particle layer, a microporous layer, a nanoporous layer, a grating sheet, a scattering sheet, a diffuser sheet, arrays of pores, arrays of crevices, arrays of air bubbles, or arrays of vacuum pores. The out-coupling structure 150 can be provided with a regular or an irregular pattern.

Please refer to FIG. 3b, which is a schematic structure of another electroluminescent device according to another embodiment of the invention. The electroluminescent device 100′ generally has the same structure as the electroluminescent device 100 shown in FIG. 3a. However, the main difference between the two electroluminescent devices 100 and 100′ is the optical out-coupling structure. As shown in FIG. 3b, the optical out-coupling structure 160 is the outer surface 110a of the substrate or superstrate 110 applied with an out-coupling surface treatment. The out-coupling surface treatment is roughening the outer surface 110a or shaping the outer surface 110a to form prism, pyramid, macrolens, microlens, micro-prism, micro-pyramid, or grating. The out-coupling structure 160 can be provided with a regular pattern or an irregular pattern.

The following examples are provided to illustrate further and to facilitate the understanding of the present invention.

### Embodiment of Invention—Example 1

In one possible embodiment of this invention, the low-index transparent electrode (the first electrode) could be a transparent conducting polymer poly(3,4-ethylenedioxythiophene):poly(styrenesulfonate) (PEDOT:PSS) with sufficient conductivity. The conducting polymer poly(3,4-ethylenedioxythiophene):poly(styrenesulfonate) (PEDOT:PSS) has been attractive due to its excellent mechanical flexibility, good transmittance and conductivity, solution processing capability, and low cost. With a conductivity almost comparable to that of ITO, high-conductivity PEDOT:PSS can be used as transparent electrodes for organic optoelectronic devices. PEDOT:PSS possesses optical properties (e.g., refractive index, n˜1.5) rather different from those of the widely used transparent conductor ITO (n˜1.9-2.1) and typical organic layers (n˜1.7-1.9).

Here, we conducted comprehensive theoretical and experimental comparisons on OLEDs adopting either the conventional high-index ITO electrode (the ITO device) or the low-index transparent PEDOT:PSS electrode (the PEDOT device), either isotropic emitters or emitters having preferentially horizontal emitting dipoles, and different layer structures. We find that with the use of low-index electrode in the device, in addition to the suppression of waveguided (WG) modes, the surface plasmon (SP) modes can also be effectively suppressed with larger emitter-to-metal distances yet with better immunity to accompanied increase of competing WG modes (induced by thicker organic layers) as in the ITO device. As a result, overall coupling efficiencies of OLED internal radiation into substrates (φ_{sub}) can be significantly enhanced over those with ITO electrodes. Through use of an external out-coupling lens on outer surfaces of substrates to effectively extract radiation within substrates, phosphorescent OLEDs adopting both the low-index electrode and the preferentially horizontal dipole emitter (with a horizontal dipole ratio Θ_{∥} of 76%) achieved a high EQE of up to ˜64%. The simulation also reveals a φ_{sub} of up to ˜85% with a Θ_{∥} of ˜100%, clearly revealing the benefit of combining low-index transparent electrodes and horizontal dipole emitters for high-efficiency OLEDs.

The ITO devices and PEDOT devices for simulation studies were green phosphorescent OLEDs having the general structure of: glass substrate/transparent anode (80-nm ITO for ITO devices or 100-nm PEDOT:PSS for PEDOT devices)/TAPC (y nm)/emitting layer [20-nm CBP doped with 8 wt. % Ir(ppy)₂(acac) or 8 wt. % Ir(ppy)₃/B3PYMPM (x nm)/Al (150 nm). TAPC (di-[4-(N,N-ditolyl-amino)-phenyl]-cyclohexane) served as the hole transport layer (HTL). CBP [4,4′-bis(carbazol-9-yl)biphenyl] doped with 8 wt. % Ir(ppy)₂(acac) [bis(2-phenylpyridine) (acetylacetonato) iridium(III)] or 8 wt. % Ir(ppy)₃ [tris(2-phenylpyridine) iridium(III)] was the phosphorescent green emitting layer (EML). Both Ir(ppy)₂(acac) and Ir(ppy)₃ exhibited similar green photoluminescence (PL) peaking around 520 nm and high PL quantum yields of >95%. According to our own and others' measurements, the less symmetric phosphorescent emitter Ir(ppy)₂(acac) doped in CBP exhibits a preferentially horizontal distribution in emitting dipole orinetations with a Θ_{∥} of 76%, while the symmetric phosphorescent emitter Ir(ppy)₃ doped in CBP shows an isotropic distribution in emitting dipole orientations with a Θ_{∥} of ˜67%. B3PYMPM (4,6-bis(3,5-di(pyridin-3-yl)phenyl)-2-methylpyrimidine) was used as the electron transport layer (ETL). Al was the cathode.

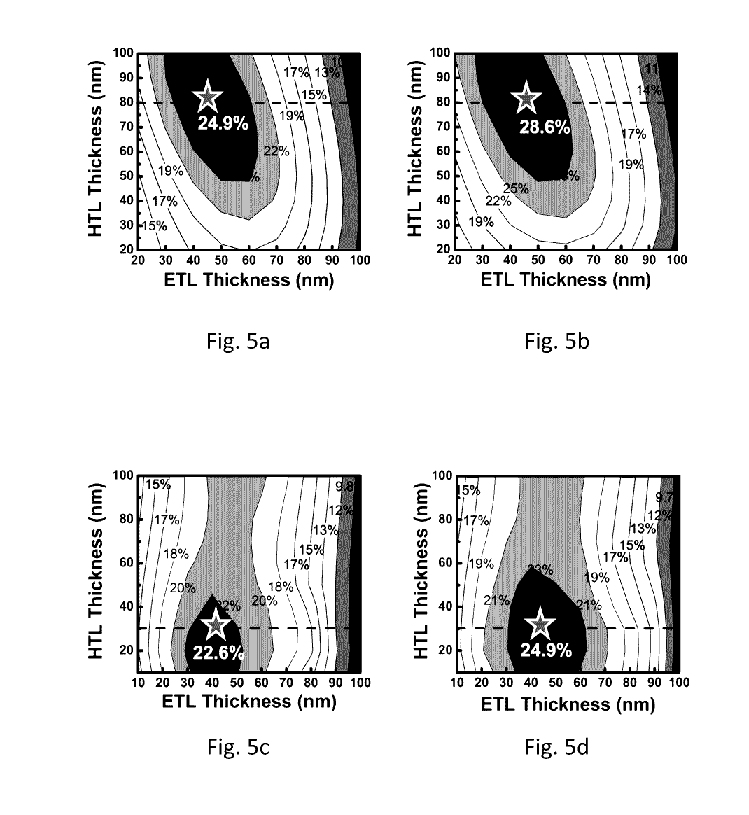

The emitting dipole orientation in a molecular emitting film can be determined by angle-resolved and polarization-resolved PL measurements. The sample consisted of a glass substrate with 15-nm-thick CBP doped with 8 wt. % Ir(ppy)₂(acac) or Ir(ppy)₃. The sample was attached to a fused silica half cylinder prism by index matching liquid. The excitation of the samples was performed with the 325-nm line of the continuous-wave He:Cd laser with a fixed excitation angle of 45°. The emission angle was changed by use of a rotation stage. The spectra were measured using a fiber optical spectrometer and a polarizing filter to distinguish p- and s-polarized light. The angle-dependent p-polarized emission at 520 nm, corresponding to the peak wavelength of the PL spectrum of the emitting layer, was detected. The emitting dipole orientation (the horizontal dipole ratio Θ_{∥}) was then determined by comparing the measured angle-dependent p-polarized emission intensity with those calculated assuming different horizontal dipole ratios (Θ_{∥}). FIGS. 4a and 4b show the measured and simulation results for CBP doped with 8 wt. % Ir(ppy)₂(acac) and Ir(ppy)₃ respectively.

To be more specific, FIGS. 4a and 4b show measured (symbols) p-polarized PL intensity (at 520 nm) of: in FIG. 4a, the CBP:8 wt. % Ir(ppy)₂(acac) emitting layer; and in FIG. 4b, the CBP:8 wt. % Ir(ppy)₃ emitting layer, as a function of the emission angle. The measured curve is compared to simulated curves (lines) with different horizontal dipole ratios Θ_{∥} (e.g., Θ_{∥}=100% for fully horizontal dipoles and Θ_{∥}=67% for the isotropic dipole orientation). The experimental data of the CBP:8 wt. % Ir(ppy)₂(acac) emitting layer and the CBP:8 wt. % Ir(ppy)₃ emitting layer can be well fitted with a horizontal dipole ratio of 76% and 67%, respectively. These values are consistent with previously reported values.

In the optical simulation of devices, the thicknesses of TAPC and B3PYMPM were varied to study influences of layer structures on coupling efficiencies of OLED internal radiation into air (φₐᵢᵣ) and into substrates (φ_{sub}). The optical model used for simulation adopts a classical oscillating electrical dipole model to represent the molecular electrical dipole transition and radiation. With plane-wave expansion of the dipole field (with each plane-wave mode being characterized by an in-plane wave vector kₜ), the full-vectorial electromagnetic fields generated by a radiation dipole is calculated, from which the distribution of the radiation power into different plane-wave modes and the far-field radiation can be obtained. Emission characteristics of an OLED are calculated by assuming that the emitting layer contains an ensemble of mutually incoherent dipole radiators with distributions in orientations, locations, and frequencies.

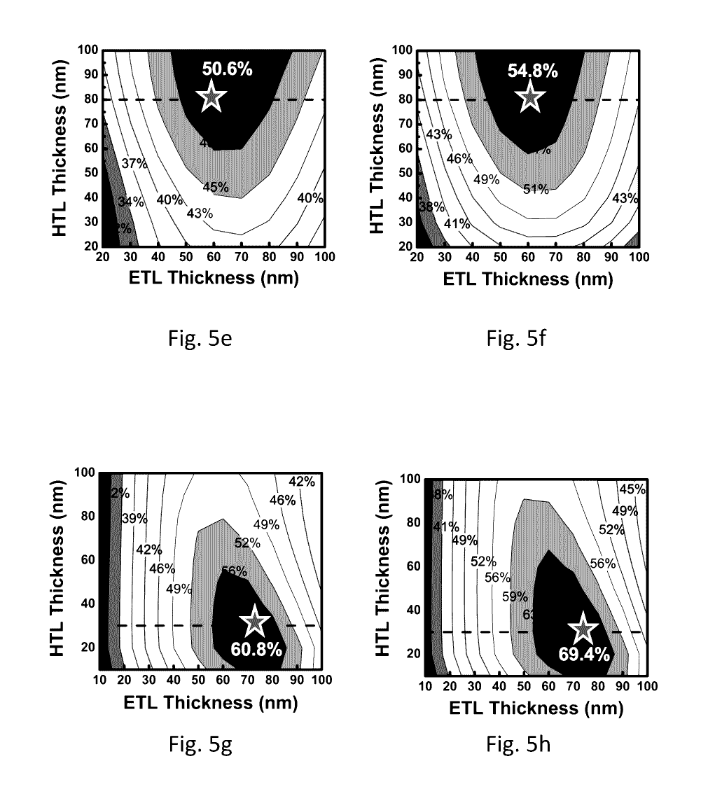

φₐᵢᵣ and φ_{sub} were calculated by locating emitting dipoles in the emitting layer and by considering the full spectral distribution (using the PL spectra of emitting layers). FIG. 5a-5d show calculated φₐᵢᵣ as a function of the HTL (TAPC) and ETL (B3PYMPM) thicknesses for the four types of devices: [ITO, Ir(ppy)₃], [ITO, Ir(ppy)₂(acac)], [PEDOT, Ir(ppy)₃], [PEDOT, Ir(ppy)₂(acac)], respectively. Similarly, FIG. 5e-5h show calculated φ_{sub} for same four devices as FIG. 5a-5d. Both φₐᵢᵣ and φ_{sub} depend significantly on the HTL and ETL thicknesses (although the dependence on the ETL thickness is in general stronger).

To be more specific, FIG. 5a-5h show calculated φₐᵢᵣ and φ_{sub} as a function of the HTL (TAPC) and ETL (B3PYMPM) thicknesses for the four device types: FIG. 5a shows φₐᵢᵣ for [ITO, Ir(ppy)₃] devices, FIG. 5b shows φₐᵢᵣ for [ITO, Ir(ppy)₂(acac)] devices, FIG. 5c shows φₐᵢᵣ for [PEDOT, Ir(ppy)₃] devices, FIG. 5d shows φₐᵢᵣ for [PEDOT, Ir(ppy)₂(acac)] devices, FIG. 5e shows φ_{sub} for [ITO, Ir(ppy)₃] devices, FIG. 5f shows φ_{sub} for [ITO, Ir(ppy)₂(acac)] devices, FIG. 5g shows φ_{sub} for [PEDOT, Ir(ppy)₃] devices, and FIG. 5h shows φ_{sub} for [PEDOT, Ir(ppy)₂(acac)] devices. Horizontal dashed lines in FIG. 5a-5h represent the roughly optimal HTL (TAPC) thickness.

From these analyses, the [PEDOT, Ir(ppy)₂(acac)] device gives maximal (d) (φₐᵢᵣ, φ_{sub}), of (˜24.9%, ˜69.4%) around the (HTL, ETL) thickness of (20-30 nm, 40-50 nm) and (20-30 nm, 70-80 nm), respectively; the [PEDOT, Ir(ppy)₃] device gives maximal (φₐᵢᵣ, φ_{sub}) of (˜21.8%, ˜60.8%) around the (HTL, ETL) thickness of (20-30 nm, 40-50 nm) and (20-30 nm, 70-80 nm), respectively; the [ITO, Ir(ppy)₂(acac)] device gives maximal (φₐᵢᵣ, φ_{sub}) of (˜28.6%, ˜54.8%) around the (HTL, ETL) thickness of (70-80 nm, 40-50 nm) and (70-80 nm, 60 nm), respectively; the [ITO, Ir(ppy)₃] device gives maximal (φₐᵢᵣ, φ_{sub}) of (˜24.9%, ˜51.0%) around the (HTL, ETL) thickness of (70-80 nm, 40-50 nm) and (70-80 nm, 60-65 nm), respectively. Several characteristics are observed in these results: (1) For ITO devices, the preferential horizontal emitter Ir(ppy)₂(acac) gives both higher (φₐᵢᵣ, φ_{sub}) by a few percent than the isotropic emitter Ir(ppy)₃. The same trend is also observed for PEDOT devices, although enhancement of φ_{sub} with horizontal dipoles is even more significant. (2) With appropriate HTL and ETL thicknesses, PEDOT devices using a same emitter could give significantly larger φ_{sub} than those achievable with ITO devices, although optimal φₐᵢᵣ's are not enhanced (indeed even a-few-percent lower than optimal values achievable with ITO devices; this is associated with different angular distributions of radiation coupled into substrates for ITO and PEDOT devices as to be manifested below). Thus, both the preferentially horizontal emitter and the low-index electrode well contribute to enhanced φ_{sub}, although the contribution from the low-index electrode appears more significant (than difference in dipole orientations here). In particular, the [PEDOT, Ir(ppy)₂(acac)] device could give >14% and >18% more φ_{sub} than the [ITO, Ir(ppy)₂(acac)] device and the [ITO, Ir(ppy)₃] device, respectively (69.4% vs. 54.8% or 51.0%). The enhanced φ_{sub} is beneficial for overall optical out-coupling of OLEDs, since radiation entering the substrate in principle can be readily extracted by applying external out-coupling structures on the outer surface of the substrate, e.g. by attaching an extraction lens.

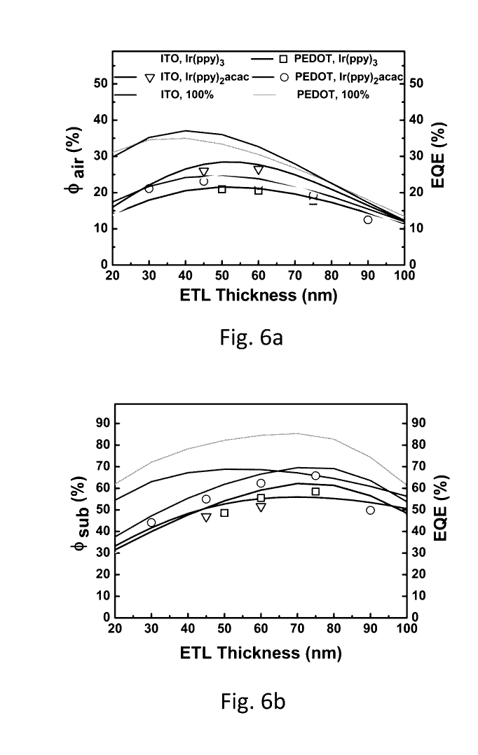

Intriguingly, regardless of device types and dipole orientations, the conditions for optimal φ_{sub} in general shift to a larger ETL thickness, compared to those for optimal φₐₙ. This is clearly manifested by comparing FIGS. 6a and 6b, which show φₐᵢᵣ and φ_{sub} as a function of the ETL thickness, respectively, at fixed and roughly optimal TAPC thicknesses (30 nm for PEDOT devices and 80 nm for ITO devices) for four device types (i.e., the cross sections along the dashed lines in FIG. 5a-5h).

FIG. 6a shows calculated φₐᵢᵣ (lines) as a function of the ETL (B3PYMPM) thickness, respectively, at fixed and roughly optimal HTL (TAPC) thicknesses (30 nm for PEDOT devices and 80 nm for ITO devices) for four device types, i.e., the cross sections along the dashed lines in FIG. 5a-5d. φₐᵢᵣ's calculated assuming 100% horizontal dipole ratio for both ITO and PEDOT devices are also shown. FIG. 6b shows calculated φ_{sub} (lines) as a function of the ETL (B3PYMPM) thickness, respectively, at fixed and roughly optimal HTL (TAPC) thicknesses (30 nm for PEDOT devices and 80 nm for ITO devices) for four device types, i.e., the cross sections along the dashed lines in FIG. 5e-5h. φ_{sub}'s calculated assuming 100% horizontal dipole ratio for both ITO and PEDOT devices are also shown. Symbols in FIG. 6a and FIG. 6b represent experiment EQEs of OLEDs measured without lens attachment and with lens attachment, respectively.

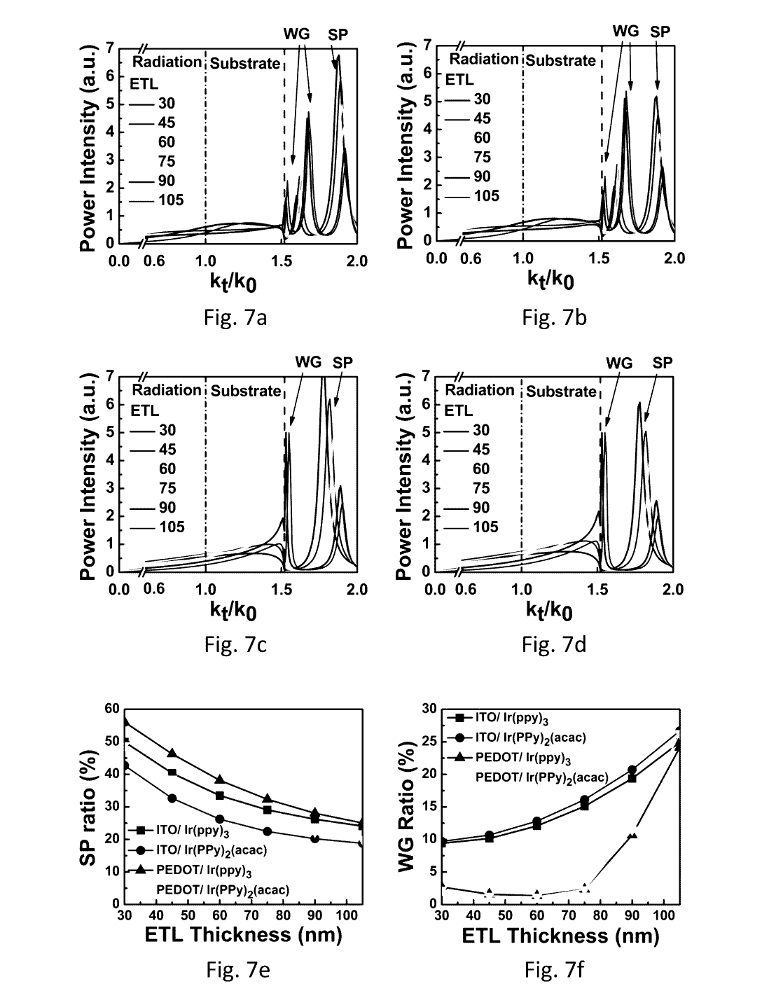

This mainly relates to different requirements for optimal φₐᵢᵣ and φ_{sub}. Optimal φₐᵢᵣ requires maximizing coupling of internally generated light into the escape cone of the air-substrate interface (thus more or less similar to satisfy constructive interference/microcavity resonance conditions along the normal direction), while optimal φ_{sub} simply requires maximizing overall coupling into the substrate regardless of its angular distribution. Thus, an optimal thickness of the ETL for optimal φₐᵢᵣ is chosen in the way so that the emitter-to-metal-electrode round-trip optical path (phase change) be roughly (2φ₁+φₘ=2pπ), where p is 0 or a natural number, φ₁ is a phase change (optical path) for a light having a main emission wavelength λ to travel from the light emitting layer to the metal electrode, and φₘ is a phase change for the light being reflected by the metal electrode. Meanwhile, an optimal thickness of the ETL for optimal φ_{sub} is chosen in the way so that the emitter-to-metal-electrode round-trip optical path (phase change) be significantly larger than (2φ₁+φₘ=2pπ), where p is 0 or a natural number, φ₁ is a phase change (optical path) for a light having a main emission wavelength λ to travel from the light emitting layer to the metal electrode, and φₘ is a phase change for the light being reflected by the metal electrode. Intriguingly, one notices that in FIG. 6b, φ_{sub}'s for both [PEDOT, Ir(ppy)₂(acac)] and [PEDOT, Ir(ppy)₃] devices show a steeper rise with the ETL thickness and the rising trend extends to a larger ETL thickness, compared to ITO devices. It indeed leads to a significantly higher optimal φ_{sub} of the [PEDOT, Ir(ppy)₂(acac)] device. A thicker ETL would help reduce SP modes and thus benefit coupling into substrates, as long as the competing and increasing WG modes (with the increase of the ETL thickness) does not overwhelm suppression of SP modes. FIG. 7a-7d show calculated mode distributions (fraction of internally generated radiation coupled into different modes as a function of kₜ/k₀; k₀ is the free-space wavevector) with varied ETL thicknesses (and fixed HTL thicknesses) for the four device types. FIG. 7e-7f show the relative fractions (intensities) of SP modes and WG modes, respectively, as a function of the ETL thickness for these four device types.

First, one notices reduction of SP modes with adoption of preferentially horizontal dipole emitters (FIG. 7b vs. 7a, FIG. 7d vs. 7c, FIG. 7e), since ratios of vertical emitting dipoles having strong coupling of radiation to SP modes are reduced. For conventional ITO devices, while SP modes decrease with the ETL thickness, yet it is accompanied by increased WG modes, leading to saturation of φ_{sub} at smaller values at smaller ETL thicknesses. In contrast, for devices with the low-index PEDOT:PSS electrode, not only WG modes are significantly suppressed at smaller ETL thicknesses, but also the drop of SP modes (with increasing ETL thickness) is not accompanied by increase of WG modes. Occurring of WG modes and its rising is postponed to a much larger ETL thickness, which explains steeper rise of φ_{sub} with the ETL thickness and achievement of significantly higher optimal φ_{sub} at larger ETL thicknesses. Overall, FIG. 7a-7f reveal intrinsic/dramatic differences in radiation behaviors between OLEDs having high-index or low-index transparent electrodes.

To experimentally characterize and verify effects of material properties and device structures on actual emission characteristics of OLEDs, the four types of devices having the fixed and roughly optimal anode/HTL structures (80/80 nm for ITO devices and 100/30 nm for PEDOT devices) and yet varied ETL thicknesses (30, 45-50, 60, 75, 90 nm etc.) were prepared and tested. According to optical simulation, the optimal ITO device requires a thicker TAPC HTL than optimal PEDOT devices (80 nm vs. 30 nm). To ensure similar electrical characteristics between these devices in experiments, for the ITO device, the 80-nm TAPC was composed of a 50-nm p-doped TAPC (doped with 3 wt. % of MoO₃) and a 30-nm non-doped TAPC. In addition, since the ETL thickness were also varied substantially, to ensure similar electrical characteristics between devices in experiments, a x-nm ETL was composed of a x-25 nm n-doped B3PYMPM (doped with 4 wt. % of Rb₂CO₃) and a 25-nm non-doped B3PYMPM. Thus experiment ITO devices had the general structure of: glass/ITO (80 nm)/p-doped TAPC (50 nm)/TAPC (30 nm)/CBP: 8 wt. % Ir(ppy)₂(acac) or 8 wt. % Ir(ppy)₃ (20 nm)/B3PYMPM (25 nm)/n-doped B3PYMPM (x-25 nm)/Al (150 nm). Experiment PEDOT devices had the general structure of: glass/double-layer PEDOT:PSS (100 nm)/TAPC (30 nm)/CBP: 8 wt. % Ir(ppy)₂(acac) or 8 wt. % Ir(ppy)₃ (20 nm)/B3PYMPM (25 nm)/n-doped B3PYMPM (x-25 nm)/Al (150 nm). (see supporting information) The PEDOT:PSS anode was composed of a 75-nm high-conductivity PEDOT:PSS layer (conductivity˜900-1000 S/cm, for lateral conduction) and a 25-nm low-conductivity PEDOT:PSS layer (conductivity˜0.1 S/cm, for hole injection), whose preparation was as described in the previous work. All layers above the ITO or PEDOT:PSS anodes were deposited by thermal evaporation and were defined by in-situ shadow masking (typically with an active device area of 1 mm²). To extract and collect overall radiation coupled into substrates, these devices were further attached with a relatively large hemisphere glass lens (having a diameter of 1.5 cm) using the index-matching oil during efficiency measurements.

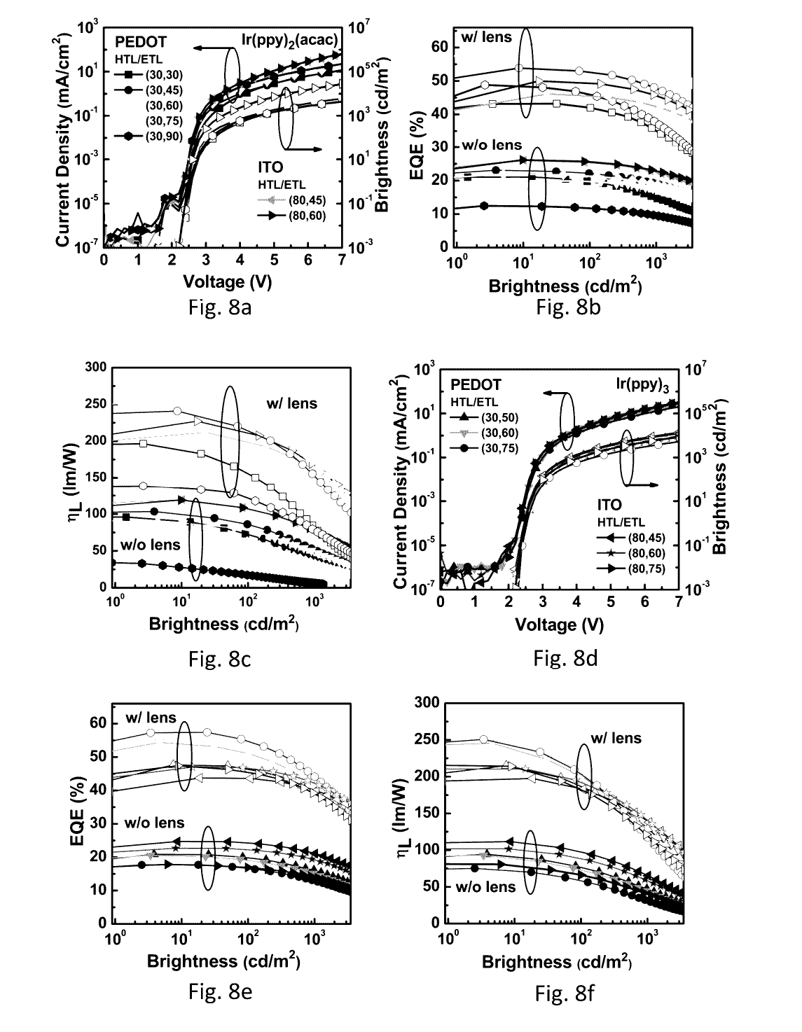

FIG. 8a shows current-voltage-luminance (I-V-L) characteristics of all [ITO, Ir(ppy)₂(acac)] and [PEDOT, Ir(ppy)₂(acac)] devices tested (without lens attachment), while FIG. 8d shows those of all [ITO, Ir(ppy)₃] and [PEDOT, Ir(ppy)₃] devices tested (without lens attachment). They all show well-behaved and similar I-V characteristics, suggesting that the difference in emission characteristics of these devices can be mainly attributed to their different optical properties and structures. FIG. 8b-8c show EQEs and luminous efficiencies (η_{L}) of all Ir(ppy)₂(acac) devices in FIG. 8a, measured either without or with lens attachment; FIG. 8e-8f show those of all Ir(ppy)₃ devices in FIG. 8d. Peak EQEs of all the devices (measured without or with lens attachment) are listed in Table 1, and are compared with calculated φₐᵢᵣ and φ_{sub} in Table 1 and in FIG. 6a-6b. Table 1 is the summary of simulation and experiment results of various OLED devices.

TABLE 1

| | PEDOT Devices | | | | | | | | ITO Devices | | | | |
|---|---|---|---|---|---|---|---|---|---|---|---|---|---|
| EML | Ir(ppy)₃ | | | Ir(ppy)₂(acac) | | | | | Ir(ppy)₃ | | | Ir(ppy)₃(acac) | |
| HTL [nm] | 30 | 30 | 30 | 30 | 30 | 30 | 30 | 30 | 80 | 80 | 80 | 80 | 80 |
| ETL [nm] | 50 | 60 | 75 | 30 | 45 | 60 | 75 | 90 | 45 | 60 | 75 | 45 | 60 |

Calculated

| | | | | | | | | | | | | | |
|---|---|---|---|---|---|---|---|---|---|---|---|---|---|
| φₐᵢᵣ [%] | 21.8 | 21.1 | 18.3 | 22.7 | 24.9 | 23.7 | 20.0 | 14.8 | 24.9 | 24.3 | 19.9 | 28.6 | 28.0 |
| φ_{sub} [%] | 53.5 | 57.9 | 60.8 | 48.5 | 59.1 | 66.6 | 69.4 | 62.9 | 46.6 | 50.6 | 51.0 | 51.2 | 54.8 |

Experiment

| | | | | | | | | | | | | | |
|---|---|---|---|---|---|---|---|---|---|---|---|---|---|
| EQE [%] | 20.9 | 20.5 | 17.7 | 21.1 | 23.1 | 22.0 | 19.3 | 12.5 | 24.7 | 22.7 | 17.9 | 26.0 | 26.4 |
| w/o lens | | | | | | | | | | | | | |
| η_{L} [lm/W] | 94.4 | 93.0 | 75.2 | 89.2 | 103.5 | 91.7 | 87.7 | 35.4 | 111.6 | 101.8 | 81.3 | 118.9 | 119.7 |
| w/o lens | | | | | | | | | | | | | |
| EQE [%] | 47.6 | 54.4 | 57.3 | 43.3 | 53.9 | 61.1 | 64.5 | 48.8 | 43.7 | 47.0 | 47.4 | 46.2 | 50.3 |
| w/lens | | | | | | | | | | | | | |
| η_{L} [lm/W] | 215.2 | 245.6 | 250.9 | 196.5 | 241.1 | 254.1 | 283.4 | 138.6 | 197.6 | 210.7 | 215.8 | 211.9 | 227.1 |
| w/lens | | | | | | | | | | | | | |

In general, EQEs measured without lens attachment agree reasonably well with calculated φₐᵢᵣ, indicating reasonably ideal internal quantum efficiencies in these devices and effectiveness of optical simulation. EQEs measured with lens attachment also follow the trend of calculated φ_{sub}, with certain deviation associated with the extraction loss (e.g. Fresnel reflection at the lens surface etc.) As expected from simulation, several characteristic trends are observed: (1) For the planar device structure and a same emitter, the high-index electrode (i.e., ITO) gives higher EQEs. (2) Yet with external out-coupling (i.e., lens attachment) to effectively extract radiation in substrates, the low-index electrode (i.e., PEDOT:PSS) gives higher optimal EQEs instead, under the condition of larger optimal emitter-to-metal distances. (3) For whatever device types (low-index or high-index electrodes, without or with external out-coupling scheme), emitters with preferentially horizontal emitting dipoles are always beneficial to EQEs of OLEDs. Thus all together, with lens attachment, the [PEDOT, Ir(ppy)₂(acac)] device with the optimal 75-nm-thick ETL gives the highest EQE and luminous efficiency (η_{L}) of up to (64.5%, 283.4 lm/W), which is significantly higher than (57.3%, 250.9 lm/W) of optimal [PEDOT, Ir(ppy)₃] device, (50.3%, 227.1 lm/W) of optimal [ITO, Ir(ppy)₂(acac)] device, and (47.4%, 215.8 lm/W) of optimal [ITO, Ir(ppy)₃] device achieved in this study, and represents a ˜14-17% higher EQE with respect to ITO devices (Table 1).

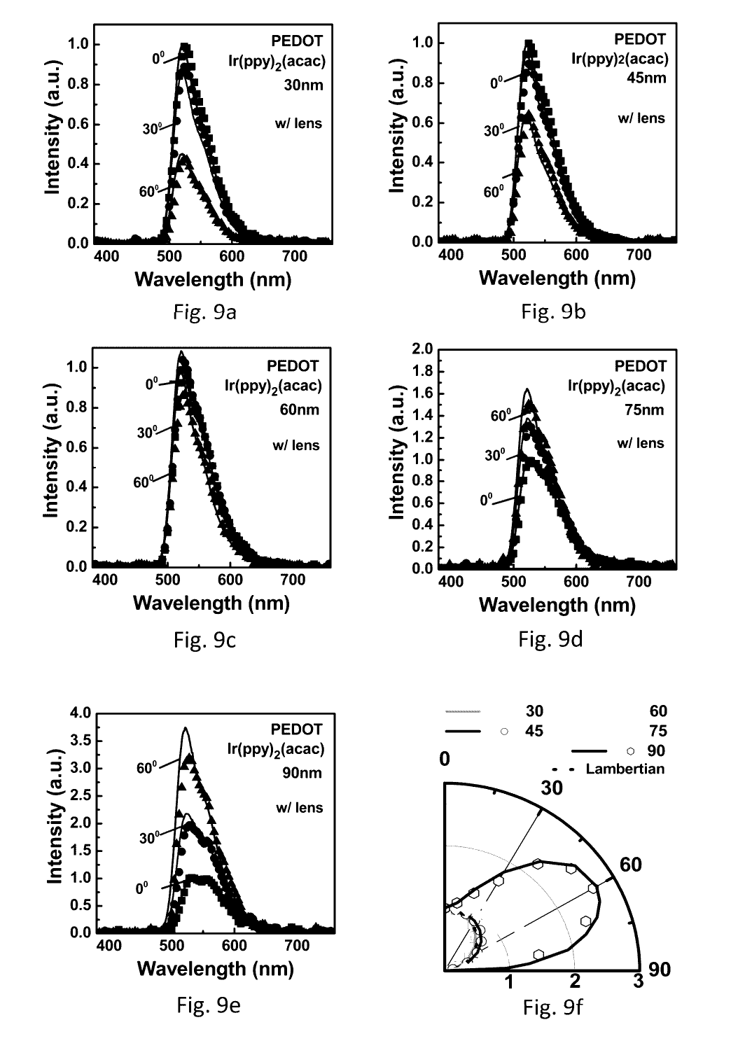

FIG. 9a-9e show measured (symbols) and calculated (lines) EL spectra with relative intensities at viewing angles of 0°, 30°, and 60° off the surface normal for the lens-attached [PEDOT, Ir(ppy)₂(acac)] devices having an ETL thickness of 30-90 nm, respectively. FIG. 9f shows measured (symbols) and calculated (lines) angular distributions of the EL intensity (normalized to 0° intensity) for these lens-attached devices, along with the Lambertian distribution. These also represent angle-resolved EL characteristics inside the substrate. Agreement between measured and calculated angle-resolved EL characteristics again confirms effectiveness of the optical simulation. As seen in FIG. 9f, the radiation pattern inside the substrate is directed toward larger angles with thicker ETL, as expected from overall power spectra of radiation coupled into substrates for these devices (k/k₀<1.52, FIG. 7d). Intriguingly, although emission patterns vary dramatically in these lens-attached devices, yet EL spectra (and thus colors) do not vary much with angles or with ETL thicknesses, which is certainly advantageous for applications. This perhaps is due to weak microcavity effects in PEDOT devices, since for ITO devices with stronger microcavity effects, variation of EL spectra is relatively larger with both angles and ETL thicknesses.

We further extend the design and the optical simulation to optimize φₐᵢᵣ and φ_{sub} achievable by varying Θ_{∥} of the emitting layer in the ITO and PEDOT devices. The simulation results are again shown in FIGS. 6a and 6b as a function of the ETL thickness (with fixed HTL thicknesses). Again, substantially higher φ_{sub} can be obtained with the PEDOT device (˜85% vs. ˜69% of ITO device) at the larger ETL thickness, even though optimal φₐᵢᵣ of PEDOT device (˜36%) is still lower than that (˜39%) of ITO device. Most importantly, it suggests that with both the low-index electrode and high Θ_{∥}, a very high EQE approaching ˜80% is possible assuming ideal (close to 100%) internal EL quantum efficiencies and effective external optical out-coupling.

In summary, we conducted comprehensive theoretical and experimental studies on OLEDs adopting either the conventional high-index ITO electrode or the low-index ITO-free PEDOT:PSS electrode, either isotropic emitters or emitters having preferentially horizontal emitting dipoles, and different layer structures. Intriguingly, with the use of low-index electrode in the device, in addition to the known suppression of waveguided modes, the surface plasmon modes can also be effectively suppressed with larger emitter-to-metal distances yet with better immunity to accompanied increase of the competing waveguided modes (induced by thicker organic layers) as in the ITO device. As a result, overall coupling efficiencies of OLED internal radiation into substrates can be significantly enhanced over those with ITO electrodes. Through effective extraction of radiation within substrates, green phosphorescent OLEDs adopting both the low-index ITO-free electrode and the preferentially horizontal dipole emitter (with a horizontal dipole ratio of 76%) achieved a high EQE of up to ˜64%. The simulation and design also reveals a very high EQE approaching ˜80% is possible with highly horizontal dipole emitters, clearly revealing the potential of combining low-index transparent electrodes and horizontal dipole emitters for high-efficiency OLEDs.

### Embodiment of Invention—Example 2

Following the general principles of the preceding embodiment example, there could be different variations and modifications of the embodiment.

For instance, in addition to the low-index transparent electrode PEDOT:PSS in example 1, other possible low-index transparent conductors (preferentially with a refractive index <1.7) include nanoporous indium tin oxide, nanoporous fluorine-doped tin oxide, nanoporous aluminum zinc oxide, nanoporous gallium zinc oxide, nanoporous tin oxide, nanoporous niobium-doped titanium oxide, their combinations, and their stacking.

### Embodiment of Invention—Example 3

For instance, the out-coupling lens attached to the substrate in example 1 may be replaced with other out-coupling optical element adjacent to the outer surface of the substrate, such as a prism, a pyramid, a hemisphere lens, a macrolens sheet, a microlens sheet, a micro-prism sheet, a micro-pyramid sheet, a micro-particle layer, a nano-particle layer, a microporous layer, a nanoporous layer, a grating sheet, a scattering sheet, a diffuser sheet, arrays of pores, arrays of crevices, arrays of air bubbles, arrays of vacuum pores etc.

### Embodiment of Invention—Example 4

For instance, the out-coupling lens attached to the substrate in example 1 may be replaced with other out-coupling surface treatment, such as shaped or roughening treated, forming regular or irregular patterns, such as prism, pyramid, macrolens, microlens, micro-prism, micro-pyramid, or grating etc.

### Embodiment of Invention—Example 5

For instance, the OLED structure in example 1 may be changed to an “inverted” OLED, i.e. the bottom transparent electrode serving as the cathode instead and the top metal electrode serving as the anode. In such “inverted” OLEDs, the low-index first (transparent) electrode is a low-index transparent cathode.

### Embodiment of Invention—Example 6

For instance, in addition to the bottom-emitting OLED structure [light emission through the first (transparent) electrode and the substrate] disclosed in example 1, the OLED structure this invention may also adopt the top-emitting structure [light emission not through the substrate but the opposite direction]. In such “top-emitting” OLEDs, the role of the substrate may be replaced by the superstrate disposed over the low-index first (transparent) electrode.

### Embodiment of Invention—Example 7

When used in lighting or display panels, the device disclosed in this invention may further be integrated with metal bus lines or metal grids having high conductivity for current conduction and for uniform current spreading over larger areas.

To sum up, according to the above-mentioned embodiments and examples of the present invention, an electroluminescent device with high optical out-coupling efficiency is provided. The electroluminescent (EL) device disclosed here in sequence comprises: (1) a first electrode (or electrode layer stack), which is transparent and with a low refractive index n_{L} less than 1.7; (2) a functional stack including a light emitting layer, wherein the emitting layer contain emitting materials having preferential horizontal emitting dipoles (relative to the layer surface) with the horizontal dipole ratio being larger than 70% and the main emission wavelength from the light emitting layer is λ; (3) a second electrode; (4) a substrate or superstrate and an optical out-coupling structure situating on the substrate or superstrate. The substrate or superstrate has an outer surface and an inner surface, the inner surface is adjacent to the first electrode layer, and the outer surface is opposite to the inner surface.

By appropriately adjusting the distance of the emitting layer to the low-refractive-index first (transparent) electrode, and the distances of the emitting layer to electrodes, the coupling efficiencies of device internal emission into substrate/superstrate are substantially increased over those of devices using conventional higher-index transparent electrodes (e.g. ITO).

The second electrode may be a reflective metal electrode having a phase change of φₘ for a incident light having a main emission wavelength λ, and the functional stack may further includes one or more functional layers from Layer 1 to Layer j, being sandwiched between the second electrode and the light emitting layer. The phase change for a light having a main emission wavelength λ to travel from the light emitting layer to the second electrode is φ₁. The distance from the light emitting layer to the second electrode may be set significantly larger than that corresponds to 2φ₁φₘ=2pπ, where p is 0 or a natural number, to significantly reduce the loss of device internal emission to surface plasmon modes associated with the second electrode (by larger emitter-to-metal electrode distance) yet without suffering simultaneous increase of competing waveguide modes (due to larger emitter-to-metal distance) and to optimize the coupling of device internal emission to the substrate or superstrate for optimal optical out-coupling of the device.

The use of the term “about” or “roughly” is before a quantitative value, the present teachings also include the specific quantitative value itself, unless specifically stated otherwise. As used herein, the term “about” refers to a ±20% variation from the nominal value unless otherwise indicated or inferred.

The above embodiments are only used to illustrate the principles of the present invention, and they should not be construed as to limit the present invention in any way. The above embodiments can be modified by those with ordinary skill in the art without departing from the scope of the present invention as defined in the following appended claims.

What is claimed is:

1. An electroluminescent device, comprising:
a substrate or superstrate having an outer surface and an opposite inner surface;
an optical out-coupling structure situating on the outer surface;
a first electrode disposed on the inner surface, wherein the first electrode being transparent and having a refractive index equal to or less than 1.7;
a functional stack disposed on the first electrode, wherein the functional stack comprises a light emitting layer containing an emitting material having preferential horizontal emitting dipoles with a horizontal dipole ratio being equal to or larger than 70%; and
a second electrode disposed on the functional stack.

2. The electroluminescent device of claim 1, wherein the refractive index of the first electrode is no smaller than a refractive index of the substrate or superstrate by more than 0.1.

3. The electroluminescent device of claim 1, wherein the functional stack further comprises:
at least one functional layer sandwiched between the light emitting layer and the second electrode, wherein a thickness of the functional layer is chosen in the way so that the emitter-to-second-electrode round-trip optical path (phase change) be significantly larger than (2φ₁+φₘ=2pπ), where p is 0 or a natural number, φ₁ is a phase change (optical path) for a light having a main emission wavelength λ to travel from the light emitting layer to the second electrode, and φₘ is a phase change for the light being reflected by the second electrode.

4. The electroluminescent device of claim 1, wherein the first electrode is selected from the group consisting essentially of PEDOT:PSS, nanoporous indium tin oxide (ITO), nanoporous fluorine-doped tin oxide, nanoporous aluminum zinc oxide, nanoporous gallium zinc oxide, nanoporous tin oxide, nanoporous niobium-doped titanium oxide, their stacking, and their combinations.

5. The electroluminescent device of claim 1, wherein the out-coupling structure is an out-coupling optical element attached to the outer surface of the substrate or superstrate.

6. The electroluminescent device of claim 5, wherein the out-coupling optical element is an optical lens, a hemisphere lens, a prism, a pyramid, a macrolens sheet, a microlens sheet, a micro-prism sheet, a micro-pyramid sheet, a micro-particle layer, a nano-particle layer, a microporous layer, a nanoporous layer, a grating sheet, a scattering sheet, a diffuser sheet, arrays of pores, arrays of crevices, arrays of air bubbles, or arrays of vacuum pores.

7. The electroluminescent device of claim 5, wherein the out-coupling structure is provided with a regular pattern or an irregular pattern.

8. The electroluminescent device of claim 1, wherein the optical out-coupling structure is the outer surface applied with an out-coupling surface treatment.

9. The electroluminescent device of claim 8, wherein the out-coupling surface treatment is roughening the outer surface or shaping the outer surface to form prism, pyramid, macrolens, microlens, micro-prism, micro-pyramid, or grating.

10. The electroluminescent device of claim 8, wherein the out-coupling structure is provided with a regular pattern or an irregular pattern.

11. The electroluminescent device of claim 1, wherein the first electrode is either an anode or a cathode of the electroluminescent device, and the second electrode is the other.

12. The electroluminescent device of claim 1, wherein the electroluminescent device is integrated with metal bus lines or metal grids having high conductivity for current conduction and for uniform current spreading over larger areas when used in lighting or display panels.
